(19) United States
(12) Patent Application Publication
(10) Pub. No.: US 2026/0047009 A1
(43) Pub. Date: Feb. 12, 2026

(54) PRINTED CIRCUIT BOARD

(71) Applicant: SAMSUNG ELECTRO-MECHANICS CO., LTD., Suwon-si (KR)

(72) Inventors: Sang Ho JEONG, Suwon-si (KR); Jong Eun PARK, Suwon-si (KR); Chang Hwa PARK, Suwon-si (KR); Sang Yun LEE, Suwon-si (KR); Hyun Hu LEE, Suwon-si (KR)

(73) Assignee: SAMSUNG ELECTRO-MECHANICS CO., LTD., Suwon-si (KR)

(21) Appl. No.: 19/177,105

(22) Filed: Apr. 11, 2025

(30) Foreign Application Priority Data
Aug. 7, 2024 (KR) 10-2024-0105227

(51) Int. Cl. H05K 1/18; H05K 1/11

(52) U.S. Cl. CPC H05K 1/181; H05K 1/113; H05K 2201/0215; H05K 2201/09036; H05K 2201/09481; H05K 2201/09527; H05K 2201/096; H05K 2201/09618

(57) ABSTRACT

A printed circuit board includes a first wiring portion including a first insulating layer and a first conductor layer, a second wiring portion including a second insulating layer and a second conductor layer, and disposed on the first wiring portion, and a bonding portion disposed between the first and second wiring portions, connecting the first and second wiring portions to each other, and including a bonding layer and a metal filler dispersed in the bonding layer, wherein the first wiring portion includes a groove formed on a surface facing the bonding portion, and the bonding portion fills the groove.

### CROSS-REFERENCE TO RELATED APPLICATIONS

This application claims benefit of priority to Korean Patent Application No. 10-2024-0105227 filed on Aug. 7, 2024 in the Korean Intellectual Property Office, the disclosure of which is incorporated herein by reference in its entirety.

### BACKGROUND

### 1. Technical Field

The present disclosure relates to a printed circuit board.

### 2. Description of Related Art

Recently, due to the development of artificial intelligence (AI) technology, a package including a memory chip such as a high bandwidth memory (HBM) for exponentially increased data processing and a processor chip such as a central processing unit (CPU), graphics processing unit (GPU), application specific integrated circuit (ASIC), filled programmable gate array (FPGA) may be used.

Research has been conducted to reduce defects occurring while a chip is mounted and to improve yield in a printed circuit board used in such a package. As the number of laminations of a substrate increases, a defect rate per layer may accumulate, which may lower overall yield, and the decrease in yield may be greater in a substrate requiring microcircuits.

### SUMMARY

An aspect of the present disclosure is to provide a printed circuit board having improved structural stability and electrical properties in coupling a plurality of wiring portions to each other.

According to an example embodiment, a printed circuit board includes a first wiring portion including a first insulating layer and a first conductor layer; a second wiring portion including a second insulating layer and a second conductor layer, and disposed on the first wiring portion; and a bonding portion disposed between the first and second wiring portions, connecting the first and second wiring portions to each other, and including a bonding layer and a metal filler dispersed in the bonding layer, wherein the first wiring portion includes a surface facing the bonding portion, the surface of the first wiring portion has a groove, and the bonding portion fills the groove.

At least a portion of the second conductor layer connected to the bonding portion may have a protrusion protruding from the second insulating layer toward the first wiring portion.

At least a portion of the protrusion may be disposed in the groove.

At least a portion of the second conductor layer disposed in the groove may be electrically separated from the other portion of the second conductor layer in the second wiring portion.

The groove may be in the first insulating layer.

A pitch of a first conductor layer disposed in an outermost portion of the first wiring portion may be shorter than a pitch of a second conductor layer disposed in an outermost portion of the second wiring portion.

The groove of the first wiring portion may be in the first conductor layer.

The first insulating layer may include a through-hole through a first surface of the first insulating layer, and in the groove, the first conductor layer may extend from the first surface of the first insulating layer to an internal wall of the through-hole.

The groove may have a shape in which a width thereof decreases from the first surface of the first insulating layer to a second surface of the first insulating layer.

The first wiring portion may include a plurality of the first conductor layer, the plurality of the first conductor layer may include a first-first conductor layer and a first-second conductor layer, the plurality of the first conductor layer may be connected to the bonding portion, and the groove may be disposed only in the first-first conductor layer.

When a direction in which the first and second wiring portions are laminated is defined as a first direction, and a direction perpendicular to the first direction is defined as a second direction, the first-first conductor layer may be disposed in a first region corresponding to a central portion in the second direction, and the first-second conductor layer may be disposed in a second region corresponding to an edge in the second direction.

In the second wiring portion, at least a portion of the second conductor layer connected to the bonding portion may have a protrusion protruding from the second insulating layer toward the first wiring portion, and a height of the protrusion in the second region may be higher than a height of the protrusion in the first region.

In the second wiring portion, at least a portion of the second conductor layer connected to the bonding portion may be buried in the second insulating layer.

The second wiring portion may include a recess, a first surface of the second conductor layer connected to the bonding portion may be disposed recessed from a first surface of the second insulating layer facing the groove, the first surface of the second conductor layer may correspond to a surface of the recess, and the bonding portion may fill the recess.

In the first wiring portion, at least a portion of a first conductor layer disposed in an innermost portion may be buried in the first insulating layer.

When a direction in which the first and second wiring portions are laminated is defined as a first direction, and a direction perpendicular to the first direction is defined as a second direction, and in the second direction, a width of the first wiring portion may be wider than a width of each of the second wiring portion and the bonding portion.

### BRIEF DESCRIPTION OF DRAWINGS

The above and other aspects, features, and advantages of the present disclosure will be more clearly understood from the following detailed description, taken in conjunction with the accompanying drawings, in which:

FIG. 1 is a block diagram illustrating an example of an electronic device system;

FIG. 2 is a perspective diagram illustrating an example of an electronic device;

FIG. 3 is a cross-sectional diagram illustrating an example of a printed circuit board;

FIG. 4 is a cross-sectional diagram illustrating a portion of a process of manufacturing a printed circuit board according an example embodiment;

FIG. 5 is a cross-sectional diagram illustrating a portion of a process of manufacturing a printed circuit board according an example embodiment;

FIG. 6 is a cross-sectional diagram illustrating an example of a printed circuit board according an example embodiment;

FIG. 7 is a cross-sectional diagram illustrating an example of a printed circuit board according an example embodiment;

FIG. 8 is a cross-sectional diagram illustrating an example of a printed circuit board according an example embodiment;

FIG. 9 is an enlarged diagram illustrating a printed circuit board, illustrating a region around a groove of a first conductor layer according an example embodiment;

FIG. 10 is an enlarged diagram illustrating a printed circuit board, illustrating a region around a groove of a first conductor layer according an example embodiment;

FIG. 11 is a cross-sectional diagram illustrating a printed circuit board according an example embodiment; and

FIG. 12 is a cross-sectional diagram illustrating a printed circuit board according an example embodiment.

### DETAILED DESCRIPTION

Hereinafter, embodiments of the present disclosure will be described as follows with reference to the attached drawings.

The present disclosure is not limited to exemplary embodiments, and it is to be understood that various modifications may be made without departing from the spirit and scope of the present disclosure. These embodiments are described in sufficient detail to enable those skilled in the art to practice the invention. Some elements may be exaggerated in the drawings, and the same elements will be indicated by the same reference numerals.

### Electronic Device

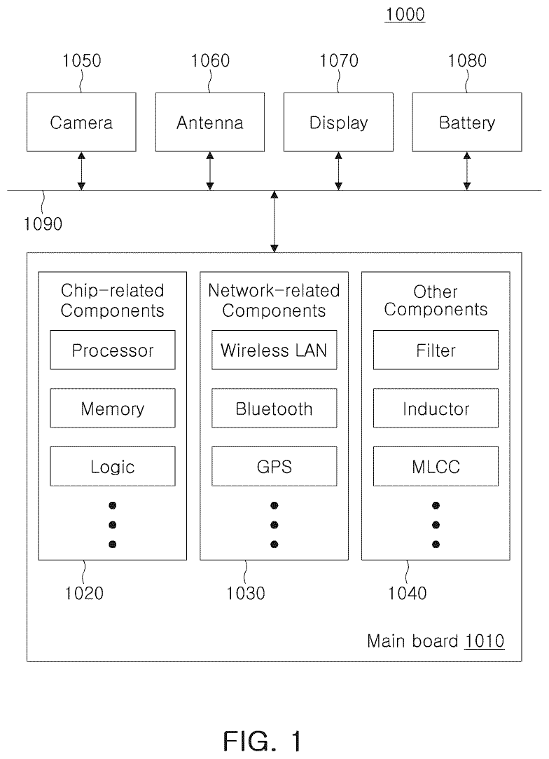

FIG. 1 is a block diagram illustrating an example of an electronic device system.

Referring to FIG. 1, an electronic device 1000 may accommodate a mainboard 1010 therein. The mainboard 1010 may include chip related components 1020, network related components 1030, other components 1040, and the like, physically or electrically connected thereto. These components may be connected to others to be described below to form various signal lines 1090.

The chip related components 1020 may include a memory chip such as a volatile memory (for example, a dynamic random access memory (DRAM)), a non-volatile memory (for example, a read only memory (ROM)), a flash memory, or the like; an application processor chip such as a central processor (for example, a central processing unit (CPU)), a graphics processor (for example, a graphics processing unit (GPU)), a digital signal processor, a cryptographic processor, a microprocessor, a microcontroller, or the like; and a logic chip such as an analog-to-digital (ADC) converter, an application-specific integrated circuit (ASIC), or the like. However, the chip related components 1020 are not limited thereto, and may also include other types of chip related components. Also, the chip related components 1020 may be combined with each other.

The network related components 1030 may include protocols such as wireless fidelity (Wi-Fi) (Institute of Electrical And Electronics Engineers (IEEE) 802.11 family, or the like), worldwide interoperability for microwave access (WiMAX) (IEEE 802.16 family, or the like), IEEE 802.20, long term evolution (LTE), evolution data only (Ev-DO), high speed packet access+ (HSPA+), high speed downlink packet access+ (HSDPA+), high speed uplink packet access+ (HSUPA+), enhanced data GSM environment (EDGE), global system for mobile communications (GSM), global positioning system (GPS), general packet radio service (GPRS), code division multiple access (CDMA), time division multiple access (TDMA), digital enhanced cordless telecommunications (DECT), Bluetooth, 3G, 4G, and 5G protocols, and any other wireless and wired protocols, designated after the abovementioned protocols. However, the network related components 1030 are not limited thereto, and may also include a variety of other wireless or wired standards or protocols. Also, the network related components 1030 may be combined with each other, together with the chip related components 1020 described above.

Other components 1040 may include a high frequency inductor, a ferrite inductor, a power inductor, ferrite beads, a low temperature co-fired ceramic (LTCC), an electromagnetic interference (EMI) filter, a multilayer ceramic capacitor (MLCC), or the like. However, other components 1040 are not limited thereto, and may also include passive components used for various other purposes, or the like. Also, other components 1040 may be combined with each other, together with the chip related components 1020 and/or the network related components 1030 described above.

Depending on a type of the electronic device 1000, the electronic device 1000 may include other components which may or may not be physically or electrically connected to the mainboard 1010. The other components may include, for example, a camera module 1050, an antenna module 1060, a display 1070, and a battery 1080. However, the other components are not limited thereto, and may include an audio codec, a video codec, a power amplifier, a compass, an accelerometer, a gyroscope, a speaker, a mass storage unit (for example, a hard disk drive), a compact disk (CD) drive, a digital versatile disk (DVD) drive, or the like. The other components may also include other components used for various purposes depending on a type of electronic device 1000.

The electronic device 1000 may be a smartphone, a personal digital assistant (PDA), a digital video camera, a digital still camera, a network system, a computer, a monitor, a tablet PC, a laptop PC, a netbook PC, a television, a video game machine, a smartwatch, an automotive component, or the like. However, the electronic device 1000 is not limited thereto, and may be any other electronic device processing data.

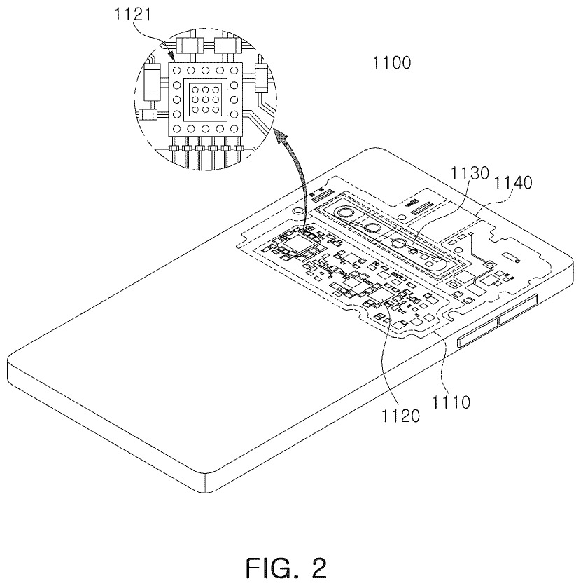

FIG. 2 is a plan diagram illustrating an example of an electronic device.

Referring to FIG. 2, an electronic device may be a smartphone 1100. A motherboard 1110 may be accommodated in the smartphone 1100, and various components 1120 may be physically or electrically connected to the motherboard 1110. Also, other components which may or may not be physically or electrically connected to the motherboard 1110, such as a camera module 1130, may be accommodated in the body 1101. A portion of the components 1120 may be the chip related components, such as, for example, a component package 1121, but an example embodiment example thereof is not limited thereto. The component package 1121 may have the form of a printed circuit board on which electronic components including active components and/or passive components are surface-mounted. Alternatively, the component package 1121 may be configured in the form of a printed circuit board in which active components and/or passive components are buried. The electronic device is not necessarily limited to the smartphone 1100, and may be other electronic devices as described above.

### Printed Circuit Board

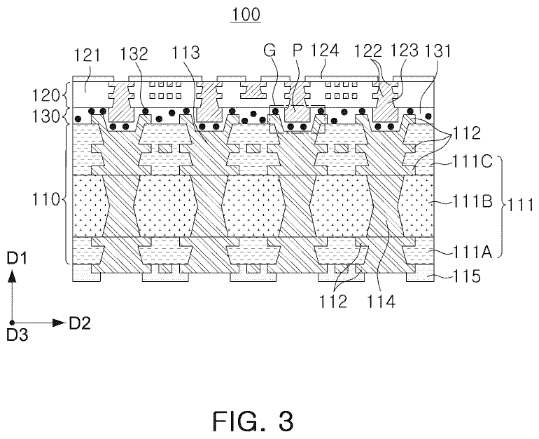

FIG. 3 is a cross-sectional diagram illustrating an example of a printed circuit board. Referring to FIG. 3, a printed circuit board 100 according to an embodiment may include a first wiring portion 110 and a second wiring portion 120, and the first and second wiring portions 110 and 120 may be connected to each other by a bonding portion 130 including a bonding layer 131 and a metal filler 132. Here, the first wiring portion 110 may include a groove G formed on a surface (the upper surface based on FIG. 3) facing the bonding portion 130, and the bonding portion 130 may be filled in the groove G. In the embodiment, the groove G may be formed in the first conductor layer 112 of the first wiring portion 110, and as described later, the groove may also be formed in the first insulating layer 111. When the groove G is formed in the first wiring portion 110 and the bonding portion 130 is filled, alignment performance and adhesion may be increased when the first and second wiring portions 110 and 120 are coupled to each other, and accordingly, structural stability of the printed circuit board 100 may be improved. Also, the bonding portion 130 may include a metal filler 132 therein in addition to the bonding function, thereby enabling the first and second wiring portions 110 and 120 to be electrically connected to each other. Hereinafter, the main components of the printed circuit board 100 may be described in greater detail.

The first wiring portion 110 may include a first insulating layer 111 and a first conductor layer 112, and in each of these layers, a plurality of layers may be laminated. The first insulating layer 111 may include a first core portion 111B and built-up portions 111A and 111C disposed on an upper portion and a lower portion thereof. In this case, the direction in which the first and second wiring portions 110 and 120 are laminated may be defined as a first direction D1, and two directions perpendicular to the first direction D1 and perpendicular to each other may be defined as a second direction D2 and a third direction D3, respectively.

The first core portion 111B may include an insulating material, and as the insulating material, an insulating resin such as a thermosetting resin such as an epoxy resin or a thermoplastic resin such as a polyimide, or a material in which the resins are mixed with an inorganic filler such as silica, or a resin impregnated into a core material such as glass fiber, glass cloth, or glass fabric together with an inorganic filler, for example, copper clad laminate (CCL), but an example embodiment thereof is not limited thereto. when desired, a core insulating layer formed of another material such as a glass substrate may be included as the first core portion 111B, or a metal core layer may be used. The first core portion 111B may be provided with a first through-via 114 and may connect the first conductor layers 112 disposed in an upper portion and a lower portion thereof.

The built-up portions 111A and 111C may be disposed on both sides of the first core portion 111B, respectively, and may have a multilayer structure. The built-up portion 111A and 111C may include an insulating material, such as an insulating resin such as a thermosetting resin such as an epoxy resin or a thermoplastic resin such as a polyimide, or a material in which the resins are mixed with an inorganic filler such as silica, or a resin impregnated in a core material such as glass fiber, glass cloth, or glass fabric together with an inorganic filler, for example, Ajinomoto build-up film (ABF), prepreg, or the like, and when desired, the built-up portions 111A and 111C may also include a photo-imageable dielectric (PID). The region included in the built-up portion 111A and 111C in the first insulating layer 111 may be obtained by laminating a plurality of insulating layers, wherein the plurality of insulating layers may include the same material or different insulating materials.

The first conductor layer 112 may include a metal material such as copper (Cu), aluminum (Al), silver (Ag), tin (Sn), gold (Au), nickel (Ni), lead (Pb), titanium (Ti), or an alloy thereof. The first conductor layer 112 may include an electroless plating layer and an electrolytic plating layer, and may further include a copper foil when desired. The first conductor layer 112 may perform various functions depending on the design of the corresponding layer. For example, the first conductor layer 112 may include a ground pattern, a power pattern, a signal pattern, or the like. Here, the signal pattern may include various signals other than a ground pattern, a power pattern, or the like, such as a data signal. Each of these patterns may include a trace, a plane, and/or a pad.

As in the embodiment, when the first conductor layer 112 has a multilayer structure, a first via 113 may be provided to connect the layers. The first via 113 may include copper (Cu), aluminum (Al), silver (Ag), tin (Sn), gold (Au), nickel (Ni), lead (Pb), titanium (Ti), or an alloy thereof as a metal material. The first via 113 may be formed together with the first conductor layer 112, and may include an electroless plating layer and an electrolytic plating layer. The first via 113 may be a filled type in which a through-hole of the first insulating layer 111 is filled with a metal material, but an example embodiment thereof is not limited thereto, and the first via 113 may also be a conformal type in which a metal material is disposed along a wall surface of the through-hole. The first via 113 may have a tapered shape in a cross-section. The first via 113 may perform various functions depending on the design of the corresponding layer. For example, the first via 113 may include a ground via, power via, signal via, or the like. Here, the signal via may include a via for transmitting various signals, such as a data signal, other than a ground via, power via, or the like.

The first solder resist layer 115 may be disposed in a lower portion of the first wiring portion 110. The first solder resist layer 115 may have an opening which partially opens a first conductor layer 112 disposed in a lowermost portion of the first wiring portion 110 among the first conductor layers 112. The first solder resist layer 115 may include a generally used solder resist material and may include a photosensitive insulating material, but an example embodiment thereof is not limited thereto.

The second wiring portion 120 may include a second insulating layer 121 and a second conductor layer 122, and in each layer, a plurality of layers are laminated. The second insulating layer 121 may include an insulating material, such as a thermosetting resin such as an epoxy resin, a thermoplastic resin such as a polyimide, or a material in which these resins are mixed with an inorganic filler such as silica, or a resin impregnated into a core material such as glass fiber (glass cloth, glass fabric) together with an inorganic filler, for example, Ajinomoto build-up film (ABF), prepreg, or the like, and when desired, the second insulating layer 121 may include a photo-imageable dielectric (PID). The second insulating layer 121 may be obtained by laminating a plurality of insulating layers, wherein the plurality of insulating layers may include the same material or different insulating materials.

The second conductor layer 122 may include a metal material, such as copper (Cu), aluminum (Al), silver (Ag), tin (Sn), gold (Au), nickel (Ni), lead (Pb), titanium (Ti), or an alloy thereof. The second conductor layer 122 may include an electroless plating layer and an electrolytic plating layer, and may further include copper foil when desired. The second conductor layer 122 may perform various functions depending on the design of a corresponding layer. For example, the second conductor layer 122 may include a ground pattern, a power pattern, a signal pattern, or the like. Here, the signal pattern may include various signals, such as a data signal, other than the ground pattern, the power pattern, or the like. Each of these patterns may include a trace, a plane, and/or a pad. In the second wiring portion 120, the second conductor layer 122 provided therein may be implemented to have a relatively narrow pitch as compared to the first conductor layer 112 through a microcircuit process.

As in the embodiment, when the second conductor layer 122 has a multilayer structure, a second via 123 may be provided to connect the layers. The second via 123 may include copper (Cu), aluminum (Al), silver (Ag), tin (Sn), gold (Au), nickel (Ni), lead (Pb), titanium (Ti), or an alloy thereof as a metal material. The second via 123 may be formed together with the second conductor layer 122, and may include an electroless plating layer and an electrolytic plating layer. The second via 123 may be a filled type in which the through-hole of the second insulating layer 121 is filled with a metal material, but an example embodiment thereof is not limited thereto, and the second via 123 may also be a conformal type in which the metal material is disposed along a wall surface of the through-hole. The second via 123 may have a tapered shape in a cross-section. In this case, depending on a manufacturing process, the first via 113 and the second via 123 may have tapered shapes in opposite directions. That is, as illustrated in the shape illustrated in FIG. 3, the second via 123 may have a shape in which the width (e.g., the width in the second direction) increases from an upper portion to a lower portion with respect to the first direction D1, whereas the first via 113 disposed in the region adjacent to the second wiring portion 120 may have a shape in which the width (e.g., width in the second direction) increases from the upper portion to the lower portion with respect to the first direction D1. The second via 123 may also perform various functions depending on the design of the corresponding layer. For example, the second via 123 may include a ground via, a power via, a signal via, or the like. Here, the signal via may include a via for transmitting various signals, such as a data signal, other than the ground via, the power via, or the like.

A second solder resist layer 124 may be disposed in an upper portion of the second wiring portion 120. The second solder resist layer 124 may have an opening which partially opens an uppermost portion of the second conductor layer 122 disposed in the second wiring portion 120. The second solder resist layer 124 may include a generally used solder resist material and may include a photosensitive insulating material.

A bonding portion 130 may be disposed between the first and second wiring portions 110 and 120, may connect the first and second wiring portions 110 and 120 to each other, and in addition to the bonding function, the portion may work as a path for electrical connection. To this end, the bonding portion 130 may include a bonding layer 131 and a metal filler 132 dispersed in the bonding layer 131. The bonding layer 131 may include an insulating resin, and may include a thermally polymerizable compound such as an epoxy compound, or a photopolymerizable compound such as an acrylate compound. The metal filler 132 may include metal particles such as nickel (Ni), cobalt (Co), silver (Ag), copper (Cu), gold (Au), and palladium (Pd), and in this case, copper (Cu) particles may be used.

The bonding portion 130 may be provided to couple a plurality of wiring portions 110 and 120 manufactured separately, and multiple substrates may be efficiently implemented therefrom. As the number of layers of the substrate increases, a defect rate may increase, and in particular, a decrease in yield may be noticeable in a substrate requiring fine circuits. When a fine circuit process is necessary for a portion of wiring portions, for example, the second wiring portion 120, a pitch of the first conductor layer 112 disposed in an uppermost portion of the first wiring portion 110 may be shorter than a pitch of the second conductor layer 122 disposed in an uppermost portion of the second wiring portion 120. In this case, by manufacturing the second wiring portion 120 in a process separate from the process of manufacturing the first wiring portion 110, a defect rate may be reduced as compared to the case in which the portions are manufactured at once. In this case, the first wiring portion 110 having a relatively wide pitch may also be manufactured in a relatively inexpensive process.

Further, in the embodiment, a groove G may be employed in the first wiring portion 110 such that alignment performance and structural stability may be improved in the region in which the first wiring portion 110 and the second wiring portion 120 are connected to each other. Specifically, the first wiring portion 110 may include a groove G formed on a surface (the upper surface based on FIG. 3) facing the bonding portion 130, wherein the bonding portion 130 may be filled in the groove G. The groove G of the first wiring portion 110 may have a function of indicating a coupling position of the first and second wiring portions 110 and 120, and as the bonding portion 130 is filled into the groove G, the bonding and electrical connection area may be expanded, such that physical and electrical coupling force between the first and second wiring portions 110 and 120 may be improved.

To further improve the coupling force, at least a portion of the second conductor layer 122 connected to the bonding portion 130 in the second wiring portion 120 may have a protrusion P protruding from the second insulating layer 121 toward the first wiring portion 110. In this case, as illustrated in the drawing, at least a portion of the protrusion P of the second conductor layer 122 may be disposed in the groove G. As a region in which the bonding portion 130 is filled, the groove G of the first wiring portion 110 may be formed in the first conductor layer 112. In this case, the first insulating layer 111 may include a through-hole formed in an upper surface, and the groove G may be formed by extending the first conductor layer 112 from an upper surface of the first insulating layer 111 to an internal wall of the through-hole. Here, the groove G may have a shape in which a width decreases from the upper surface to the lower surface of the first insulating layer 111 with respect to the first direction D1.

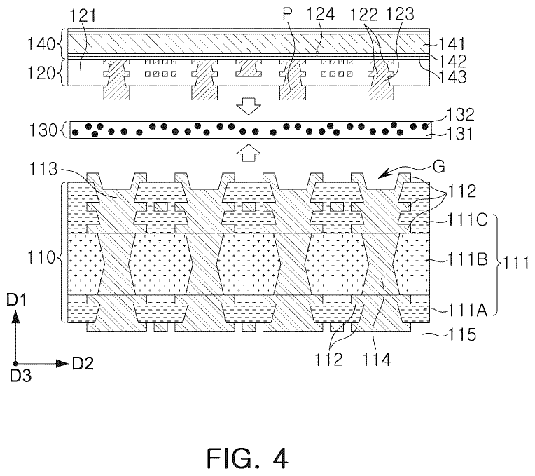

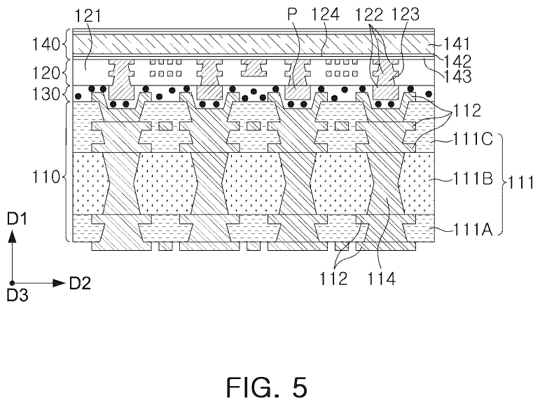

Referring to the process examples in FIGS. 4 and 5, as described above, the first wiring portion 110 and the second wiring portion 120 may be manufactured separately, and the bonding portion 130 may be disposed therebetween and may be bonded thereto under high temperature and high pressure conditions. During this process, forming and curing of the bonding layer 131 may be performed, and the first wiring portion 110 and the second wiring portion 120 may be physically and electrically connected to each other. The second wiring portion 120 may be formed in a carrier substrate 140, the carrier substrate 140 may be provided as a detachable copper foil (DCF substrate), and specifically, the carrier substrate 140 may include an insulating layer 141 and a copper foil 142 formed on both sides. Also, the carrier substrate 140 may further include a barrier layer 143 for a separate process from the process of forming the second wiring portion 120. Subsequent to the above-described bonding process, the carrier substrate 140 may be separated from the second wiring portion 120, and thereafter, solder resist layers 115, 124 may be formed, thereby obtaining the printed circuit board 100.

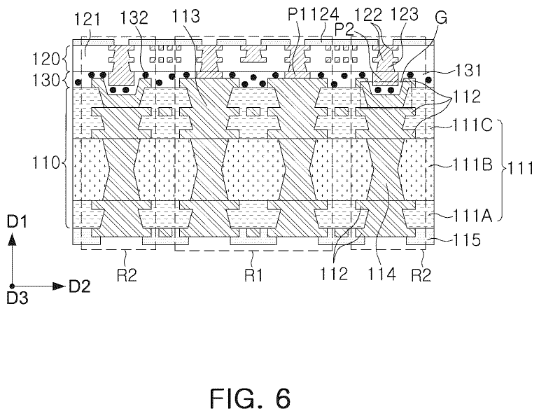

Hereinafter, other embodiments of the printed circuit board may be described with reference to FIGS. 6 to 12. First, as in the embodiment in FIG. 6, the groove G of the first wiring portion 110 may be formed only in a portion of the first conductor layer 112 connected to the bonding portion 130. In other words, the groove G may be formed in a portion of the first conductor layer 112 connected to the bonding portion 130, and the groove may not be formed in the other portion. In this case, among the first conductor layers 112, the first conductor layer 112 in which the groove G is formed and the first conductor layer 112 in which the groove G is not formed may be separated by region depending on the type of component disposed thereon. For example, among the first conductor layers 112 connected to the bonding portion 130, the first conductor layer 112 (first-first conductor layer) having the groove G may be disposed in the first region R1 corresponding to the central portion in the second direction D2, and the first conductor layer 112 (first-second conductor layer) not having the groove G among the first conductor layer 112 connected to the bonding portion 130 may be disposed in the second region corresponding to an edge in the second direction D2. In this case, in the second wiring portion 120, at least a portion of the second conductor layer 122 connected to the bonding portion 130 may have protrusions P1 and P2 protruding from the second insulating layer 121 toward the first wiring portion 110, and a height of the protrusion P2 of the second region R2 may be higher than that of the protrusion P1 of the first region R1. Accordingly, the groove G and the protrusion P2 may be aligned in the second region R2, and coupling between pads may be obtained in the first region R1. On the second wiring portion 120, the regions corresponding to the first region R1 and the second region R2 may have pitches adjusted differently depending on the components disposed thereon. For example, a pitch of the second conductor layer 122 in the first region R1 may be shorter than a pitch of the second conductor layer 122 in the second region R2, and herein, the pitch of the second conductor layer 122 may be the pitch of the region exposed to an upper portion. In this case, on the second wiring portion 120, the first region R1 may be provided as a region in which the chip is disposed, and the second region R2 may be provided as a region in which the memory is disposed.

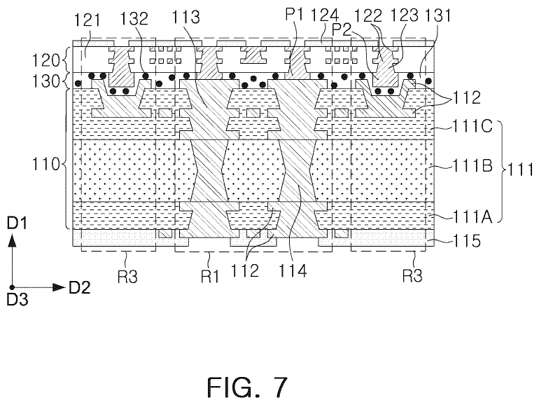

Thereafter, as in the embodiment in FIG. 7, the second conductor layer 122 disposed in groove G may be implemented to be electrically separated from another second conductor layer 122. Specifically, at least a portion of the second conductor layer 122 disposed in groove G among the second conductor layers 122 may be electrically separated from the other portion of the second conductor layer 122, and in this case, the second conductor layer 122 disposed in groove G may correspond to a dummy pad for performing a function of coupling the above-described first and second wiring portions 110 and 120 to each other and a function of preventing an overflow of the bonding layer 131 during a bonding process. The second conductor layer 122 disposed in groove G may be disposed in a mounting region of a component, for example, the other space R3 of the printed circuit board 100 rather than the first region R1 and the second region R2 described above. The structure in which at least a portion of the second conductor layer 122 disposed in the groove G among the second conductor layers 122 may be electrically separated from the other portion of the second conductor layer 122 may indicate that the layers are separated in the second wiring portion 120, and may be electrically connected to each other through the first wiring portion 110.

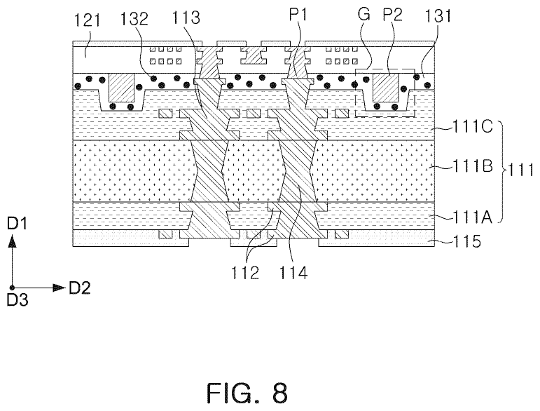

Thereafter, as in the embodiment in FIG. 8, the groove G of the first wiring portion 110 may be formed in the first insulating layer 111, and even in this case, the bonding portion 130 may be filled in the groove G of the first insulating layer 111 and may enhance physical and electrical coupling between the first and second wiring portions 110 and 120. In this case, similarly to the embodiment in FIG. 7, at least a portion of the second conductor layer 122 disposed in the groove G among the second conductor layers 122 may be electrically separated from the other portion of the second conductor layer 122, and in this case, the second conductor layer 122 disposed in the groove G may correspond to a dummy pad for performing a function of coupling the first and second wiring portions 110 and 120 to each other and a function of preventing an overflow of the bonding layer 131 during a bonding process. The second conductor layer 122 disposed in groove G may be disposed in the other space of the printed circuit board 100 other than the region in which the component is mounted, for example, the first region R1 and the second region R2 described above. At least a portion of the second conductor layer 122 disposed in the groove G may indicate that the structure may be electrically separate from the other portion of the second conductor layer 122 in the second wiring portion 120, and may be electrically connected to each other through the first wiring portion 110.

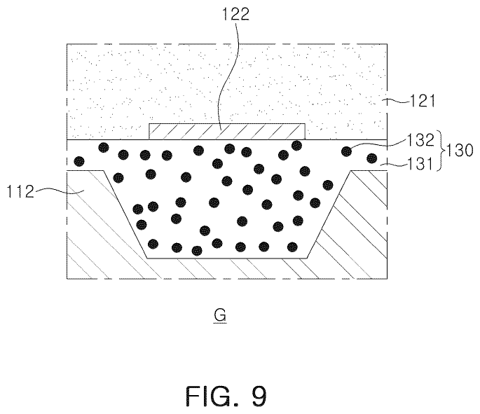

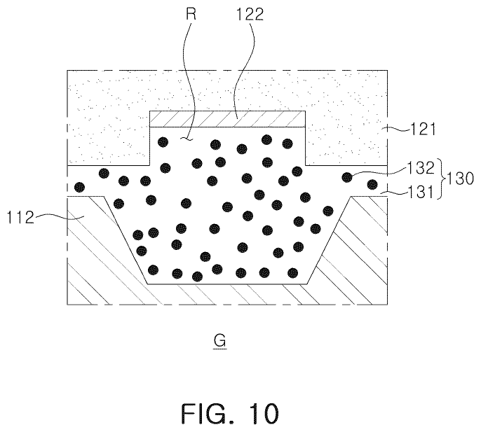

FIGS. 9 and 10 are enlarged diagrams illustrating a printed circuit board, illustrating a region around a groove of a first conductor layer according an example embodiment, and in the embodiment in FIG. 9, the second conductor layer 122 may be buried rather than protruding. Specifically, at least a portion of the second conductor layer 122 connected to the bonding portion 130 in the second wiring portion 120 may be buried in the second insulating layer. Also, as in the embodiment in FIG. 10, the lower surface of the second conductor layer 122 connected to the bonding portion 130 in the second wiring portion 120 may be disposed in an upper portion than a lower surface of the second insulating layer 121 and may form a recess R. In this case, the bonding portion 130 may fill the recess R of the second wiring portion 120, and accordingly, the coupling force between the first wiring portion 110 and the second wiring portion 120 may be improved.

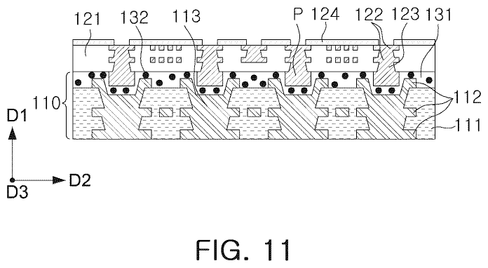

Thereafter, the example in FIG. 11 may be different from the aforementioned embodiment in terms of the specific structure of the first wiring portion 110. In this case, at least a portion of the first conductor layer 112 disposed in a lowermost portion of the first wiring portion 110 may be buried in the first insulating layer 111.

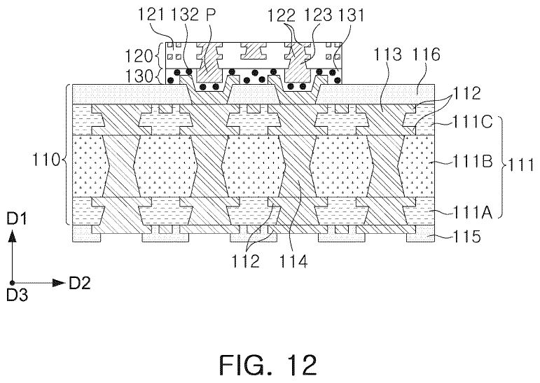

Thereafter, as in the embodiment in FIG. 12, the first and second wiring portions 110 and 120 may have different widths. Specifically, the width in the second direction D2 of the first wiring portion 110 may be wider than the widths in the second direction D2 of the second wiring portion 120 and the bonding portion 130, and the second wiring portion 120 having a relatively narrow width may be used as an interposer. In this case, a solder resist layer 116 may be disposed on an upper surface of the first wiring portion 110.

According to the aforementioned example embodiments, structural stability and electrical properties of a printed circuit board may improve in coupling a plurality of wiring portions to each other.

In the present disclosure, a height, a width, a pitch, and the like, may be measured using a scanning microscope, an optical microscope, or the like, based on a cross-section of a printed circuit board that has been polished or cut. The cut cross-section may be a vertical cross-section or a horizontal cross-section, and each value may be measured based on the required cut cross-section. Other methods and/or tools appreciated by one of ordinary skill in the art, even if not described in the present disclosure, may also be used.

While the example embodiments have been illustrated and described above, it will be apparent to those skilled in the art that modifications and variations could be made without departing from the scope of the present disclosure as defined by the appended claims.

What is claimed is:

1. A printed circuit board, comprising:
a first wiring portion including a first insulating layer and a first conductor layer;
a second wiring portion including a second insulating layer and a second conductor layer, and disposed on the first wiring portion; and
a bonding portion disposed between the first and second wiring portions, connecting the first and second wiring portions to each other, and including a bonding layer and a metal filler dispersed in the bonding layer,
wherein the first wiring portion includes a surface facing the bonding portion, the surface of the first wiring portion has a groove, and the bonding portion fills the groove.

2. The printed circuit board of claim 1, wherein at least a portion of the second conductor layer connected to the bonding portion has a protrusion protruding from the second insulating layer toward the first wiring portion.

3. The printed circuit board of claim 2, wherein at least a portion of the protrusion is disposed in the groove.

4. The printed circuit board of claim 3, wherein at least a portion of the second conductor layer disposed in the groove is electrically separated from the other portion of the second conductor layer in the second wiring portion.

5. The printed circuit board of claim 3, wherein the groove is in the first insulating layer.

6. The printed circuit board of claim 1, wherein a pitch of a first conductor layer disposed in an outermost portion of the first wiring portion is shorter than a pitch of a second conductor layer disposed in an outermost portion of the second wiring portion.

7. The printed circuit board of claim 1, wherein the groove is in the first conductor layer.

8. The printed circuit board of claim 7,
wherein the first insulating layer includes a through-hole through a first surface of the first insulating layer, and
wherein, in the groove, the first conductor layer extends from the first surface of the first insulating layer to an internal wall of the through-hole.

9. The printed circuit board of claim 8, wherein the groove has a shape in which a width thereof decreases from the first surface of the first insulating layer to a second surface of the first insulating layer.

10. The printed circuit board of claim 1, wherein the first wiring portion includes a plurality of the first conductor layer, the plurality of the first conductor layer includes a first-first conductor layer and a first-second conductor layer, the plurality of the first conductor layer is connected to the bonding portion, and the groove is disposed only in the first-first conductor layer.

11. The printed circuit board of claim 10, wherein when a direction in which the first and second wiring portions are laminated is defined as a first direction, and a direction perpendicular to the first direction is defined as a second direction, the first-first conductor layer is disposed in a first region corresponding to a central portion in the second direction, and the first-second conductor layer is disposed in a second region corresponding to an edge in the second direction.

12. The printed circuit board of claim 11,
wherein, in the second wiring portion, at least a portion of the second conductor layer connected to the bonding portion has a protrusion protruding from the second insulating layer toward the first wiring portion, and
wherein a height of the protrusion in the second region is higher than a height of the protrusion in the first region.

13. The printed circuit board of claim 1, wherein, in the second wiring portion, at least a portion of the second conductor layer connected to the bonding portion is buried in the second insulating layer.

14. The printed circuit board of claim 13,
wherein the second wiring portion includes a recess,
a first surface of the second conductor layer connected to the bonding portion is disposed recessed from a first surface of the second insulating layer facing the groove,
the first surface of the second conductor layer corresponds to a surface of the recess, and
wherein the bonding portion fills the recess.

15. The printed circuit board of claim 13, wherein, in the first wiring portion, at least a portion of a first conductor layer disposed in an innermost portion is buried in the first insulating layer.

16. The printed circuit board of claim 1, wherein, when a direction in which the first and second wiring portions are laminated is defined as a first direction, and a direction perpendicular to the first direction is defined as a second direction, and in the second direction, a width of the first wiring portion is wider than a width of each of the second wiring portion and the bonding portion.

17. The printed circuit board of claim 1, wherein the metal filler includes at least one selected from nickel (Ni) particles, cobalt (Co) particles, silver (Ag) particles, copper (Cu) particles, gold (Au) particles, and palladium (Pd) particles.

18. The printed circuit board of claim 1, wherein the metal filler includes copper (Cu) particles.

19. The printed circuit board of claim 1, wherein the bonding layer includes an insulating resin.
